(19) United States
(12) Patent Application Publication
(10) Pub. No.: US 2024/0234604 A1
(43) Pub. Date: Jul. 11, 2024

(54) SOLAR MODULE AND USE OF A PROTECTIVE COVER

(71) Applicant: HANWHA Q CELLS GMBH, Bitterfeld-Wolfen (DE)

(72) Inventors: Peter CLAWIN, Bitterfeld-Wolfen (DE); Sven RISSLAND, Bitterfeld-Wolfen (DE); Christian STELLING, Bitterfeld-Wolfen (DE); Björn FAULWETTER QUANDT, Bitterfeld-Wolfen (DE); Christian TAUBITZ, Bitterfeld-Wolfen (DE); Ronny BAKOWSKIE, Bitterfeld-Wolfen (DE); Henry PARUSEL, Bitterfeld-Wolfen (DE); Thoralf HARDER, Bitterfeld-Wolfen (DE); Sven THORMANN, Bitterfeld-Wolfen (DE)

(21) Appl. No.: 18/289,472

(22) PCT Filed: May 5, 2022
(86) PCT No.: PCT/DE2022/100349

§ 371 Date: Dec. 6, 2023

(30) Foreign Application Priority Data
May 6, 2021 (DE) 10 2021 111 786.0

(51) Int. Cl. H01L 31/049; H01L 31/05

(52) U.S. Cl. CPC H01L 31/049; H01L 31/0512; H01L 31/0516

(57) ABSTRACT

A solar module, having: a panel-shaped front-face element and a panel-shaped rear-face element, an encapsulation material which is arranged between the front-face element and the rear-face element, a plurality of solar cells which are arranged between the front-face and the rear-face element and are encapsulated in an encapsulation volume so as to be weather-resistant by means of the front-face element, the rear-face element, and the encapsulation material surrounding the solar cells in the form of a laminate, and cell connectors which are arranged and designed such that the solar cells are electrically connected together. A metallization of the solar cells and/or the cell connectors are provided with a protective layer over the entire surface or over a large part of the surface thereof.

### RELATED APPLICATIONS

The present application is a National Phase entry of PCT Application No. PCT/DE2022/100349, filed May 5, 2022, which claims priority to German Patent Application No. 10 2021 111 786.0, filed May 6, 2021, the disclosures of which are hereby incorporated by reference herein in their entirety.

### FIELD OF THE INVENTION

The invention relates to a solar module and to the use of a protective layer. A solar module customarily comprises a planar front element, a planar back element and an encapsulation material for solar cells that is disposed between the front element and the back element. Moreover, the solar module comprises a plurality of solar cells which are disposed between the front element and the back element and are weatherably encapsulated in an encapsulation volume by means of the front element, the back element and the encapsulation material enclosing the solar cells in the form of a laminate. The solar module also contains cell connectors which are disposed and designed in such a way to electrically interconnect the solar cells.

The solar module has a front through which sunlight enters during operation and a back which is opposite the front and faces away from sunlight.

The solar cells, which are especially produced on the basis of semiconductor wafers, likewise each comprise a front through which sunlight enters during operation and a back which is opposite the front and faces away from sunlight. Each solar cell comprises a substrate and a metallization customarily in the form of a front metallization and a back metallization, between which the substrate is situated. In the solar module, the front metallizations and the back metallizations of the solar cells are in mechanical contact with the encapsulation material.

During operation of the solar module, the encapsulation material can respond to the influence of heat and moisture by releasing one or more corrosive reaction products. Moisture generally penetrates the solar module laminate via the peripheral edges of the solar module. The front element and back element are customarily permanently weatherproofed. The critical region is the edges of the solar module laminate. Provided thereon are structural protective measures to counteract the penetration of liquid, but they do not offer the same barrier effect compared to the permanent tightness of the front and back elements to penetrating moisture. If the encapsulation material is EVA (ethylene vinyl acetate), penetrating moisture can lead to the formation of acetic acid as corrosive reaction product due to hydrolysis of the EVA.

The corrosive reaction product(s) in turn react(s) with the front and back metallizations of the solar cell, which leads to defects. If the front metallizations are in the form of finger electrodes, a reaction between the finger electrodes and the corrosive reaction product leads, for example, to finger contact loss (FCL) and power loss of the solar module. The likewise possible corrosion of the electrical cell contacting in the form of cell connectors also leads to considerable power losses of the solar module.

In order to solve this problem, it is known from prior art not supported by publications to provide the solar module with uniform outer barriers such as metallization, metal foils, polymers or the like or to use encapsulation materials having a better barrier effect. However, there is still a need for a solar module having optimized long-term performance and resistance to penetrating moisture.

### SUMMARY

It is therefore an object of the present invention to provide a solar module having optimized long-term performance.

According to the invention, the object is achieved by a solar module as claimed in the claims. Advantageous modifications and developments are described in the claims.

According to the invention, a metallization of the solar cells and/or the cell connectors are uniformly or largely provided with a protective layer.

The invention is based on the fundamental finding that especially decomposition of the encapsulation material corrodes the metals from the metallization of the solar cell. Studies by the inventors have shown that the envisaged protective layer prevents or at least significantly reduces this corrosion. Application of the protective layer prevents interaction and/or reaction between the solar cell metallization and the encapsulation material that lead to degradation effects, thus achieving protection for the front metallization and/or the cell connectors. The solar module thereby receives improved long-term stability with respect to the power delivered.

The expression “largely provided with a protective layer” is to be understood to mean that >90%, preferably >95%, of their respective surface are provided with the protective layer. This means a surface that is not in contact with other parts of the solar cell; rather, what is meant is an exposed surface of the front metallization and/or the cell connector after completion of production of the solar cell for lamination into the encapsulation material.

The metallization of the solar cells provided with the protective layer can be the respective front metallization and/or back metallization of the solar cells.

The solar cells can be in the form of monofacial or bifacial solar cells. Monofacial solar cells can only use light incident on their front, whereas a bifacial solar cell can make use of incident sunlight from two sides. The bifacial solar cell can use not only direct light incidence via the front, but also direct or indirect light incidence via the back, for example in the form of reflected sunlight in the case of the latter. The monofacial solar cell preferably comprises the front metallization in the form of finger electrodes and back metallization in the form of a uniform metallization. The bifacial solar cell preferably comprises the front metallization in the form of finger electrodes and the back metallization in the form of finger electrodes. Preferably, the metallization is provided with the protective layer when it is in the form of finger electrodes.

In a preferred embodiment, the front metallization of the solar cells is uniformly or largely provided with the protective layer. This embodiment is especially preferred if the solar cells are monofacial solar cells comprising a front metallization in the form of finger electrodes and the back metallization in the form of a uniform metallization.

If the solar cells are bifacial, and if they comprise the front metallization in the form of finger electrodes and the back metallization in the form of finger electrodes, the front metallization of the solar cells and the back metallization of the solar cells are preferably provided with the protective layer.

In accordance with the use of the respective solar cells having bifacial or monofacial properties, the solar module produced using said solar cells is also bifacial or monofacial. In the case of the bifacial solar module, a film or glass substantially transparent to light is preferably used as back element. This makes it possible to use light that passes through the module unused and reflected light from the surrounding area via the back of the solar module.

The solar cells preferably each comprise the front metallization in the form of finger electrodes. Preferably, the finger electrodes are uniformly or largely provided with the protective layer, whereas the rest of the front of the solar cell is protective layer-free, i.e., not provided with said protective layer. The expression “protective layer-free” means that overlaps of the protective layer in the submillimeter range at the edge of the finger electrodes are disregarded. The protective layer prevents or at least reduces finger corrosion and FLC.

If the solar cells each comprise the back metallization in the form of finger electrodes, these finger electrodes are preferably likewise uniformly or largely provided with the protective layer, whereas the rest of the back of the solar cell is protective layer-free, i.e., not provided with the protective layer.

In a preferred embodiment, a material of the protective layer is selected from the group consisting of varnish, polyolefin and/or self-assembled monolayer.

The self-assembled monolayer preferably comprises a long-chain compound having a functional group that is designed to carry out chemisorption on a metal surface. More preferably, the self-assembled monolayer, also called SAM, consists of said compound. The metal surface is preferably a silver and/or aluminum surface. The expression “long-chain” is preferably to be understood to mean a carbon chain having at least 6, preferably 10, preferably 12, carbon atoms in a chain arrangement. The chain is preferably an alkyl chain. As an alternative or additional preference, the carbon chain can also comprise alkene, alkyne or aromatic units.

Preferably, the front metallization comprises silver and/or aluminum. More preferably, it consists essentially of silver and/or aluminum. The back metallization preferably likewise comprises silver and/or aluminum or consists essentially of silver and/or aluminum.

Preferably, the self-assembled monolayer is based on one or more alkylamines, one or more alkanethiols and/or one or more carboxylic acids. If desired, the functional groups of the stated compounds can be provided with protective groups.

In a preferred embodiment, the varnish is organic. This means that it contains at least one organic compound which forms the protective layer.

The polyolefin is, for example, applicable to the cell connectors and/or to the metallization in the form of a polyolefin strip.

In a preferred embodiment, the protective layer is metal-free. This means that the starting material of the protective layer is metal-free and that the protective layer per se does not contain metal, but is designed to carry out chemisorption with the metal surface of the metallization or the cell connectors.

Preferably, the encapsulation material is EVA (ethylene vinyl acetate). EVA is a transparent plastic. During solar module production, this encapsulation material melts at high temperatures in a laminator and encloses the solar cells, as a result of which they are protected from environmental influences.

The invention further relates to the use of a metal-free protective layer for coating a metallization of a solar cell and/or a cell connector intended for electrical interconnection of multiple solar cells in a solar module.

Advantages, modifications and developments of the protective layer that have been described in relation to the solar module apply, mutatis mutandis, to the use of the protective layer. The protective layer used corresponds to the protective layer described above in relation to the solar module.

### BRIEF DESCRIPTION OF THE DRAWINGS

The invention will be elucidated below on the basis of exemplary embodiments with reference to the figures. In the schematic figures which are not to scale:

FIG. 1 shows a cross-sectional view of a solar module according to the prior art;

FIG. 2 shows a cross-sectional view of a solar module according to a first embodiment; and

FIG. 3 shows a cross-sectional view of a solar module according to a second embodiment.

### DETAILED DESCRIPTION

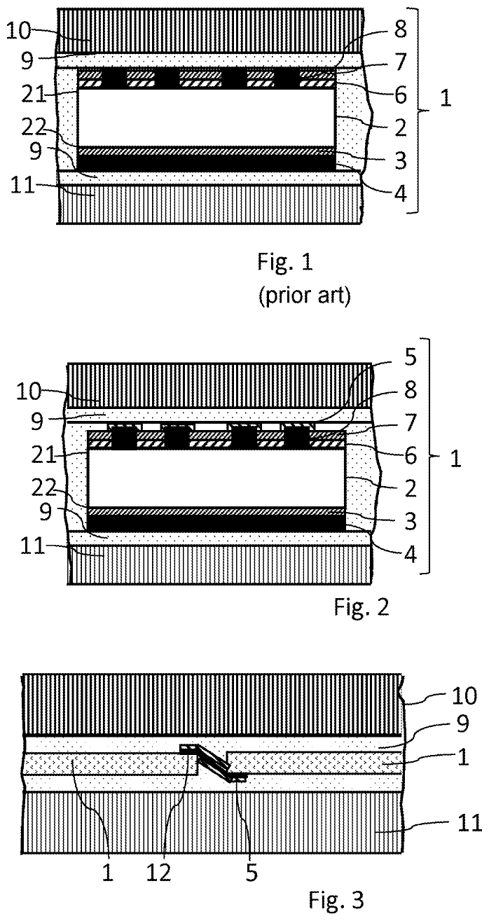

FIG. 1 shows a cross-sectional view of a solar module according to the prior art. The solar module comprises a planar front element 10, a planar back element 11 and an encapsulation material 9 which is disposed between the front element 10 and the back element 11. Furthermore, the solar module comprises a plurality of electrically interconnected wafer solar cells 1, of which only one is exemplified. The solar cells are disposed between the front element 10 and the back element 11 and are permanently weatherably encapsulated in an encapsulation volume by means of the front element 10, the back element 11 and the encapsulation material 9 enclosing the solar cells 1 in the form of a laminate. The solar cell 1 comprises a substrate 2 having a front 21 and a back 22. Rear-facedly, i.e., on the back 22, the solar cell 1 comprises a back passivation layer 3 and a uniformly disposed back metallization 4. On the front 22, there are disposed a doping layer 6, a front passivation layer 7 and a front metallization 8 in the form of finger electrodes. The solar cell 1 is electrically interconnected with the other solar cells via so-called cell connectors in order to form a string of solar cells. The cell connectors and the adjacent solar cells are not depicted.

FIG. 2 shows a cross-sectional view of a solar module according to a first embodiment. The solar module shown in FIG. 2 corresponds to the solar module shown in FIG. 1 and differs in that the front metallization 8 of the solar cell 1 is uniformly or largely provided with a protective layer 5. The finger electrodes are uniformly or largely provided with the protective layer 5, whereas the rest of the front of the solar cell 1 is protective layer-free.

FIG. 3 shows a cross-sectional view of a solar module according to a second embodiment. The solar module comprises a planar front element 10, a planar back element 11 and an encapsulation material 9 which is disposed between the front element 10 and the back element 11. Furthermore, the solar module comprises a plurality of solar cells 1, of which two are shown. The solar cells are disposed between the front element 10 and the back element 11 and are permanently weatherably encapsulated in an encapsulation volume by means of the front element 10, the back element 11 and the encapsulation material 9 enclosing the solar cells 1 in the form of a laminate. The solar cells 1 can be in the form of the solar cell shown in FIG. 1 or 2. The solar module further comprises cell connectors 12, of which one is shown and which are disposed and designed in such a way that they electrically interconnect the solar cells 1. The cell connectors 12 are uniformly or largely provided with a protective layer 5. Said protective layer 5 protects the metal of the cell connector 12 from corrosion in accordance with the foregoing discussions concerning the function of the protective layer 5 on the front metallization 8. The discussions in this respect concerning FIG. 2 apply, mutatis mutandis, to the cell connectors 12 shown in FIG. 3.

### LIST OF REFERENCE SIGNS

1 solar cell
2 substrate
3 back passivation layer
4 back metallization
5 protective layer
6 doping layer
7 front passivation layer
8 front metallization
9 encapsulation material
10 front encapsulation element
11 back encapsulation element
12 cell connector
21 front
22 back

1. A solar module comprising:
a planar front element and a planar back element,
an encapsulation material which is disposed between the front element and the back element,
a plurality of solar cells which are disposed between the front element and the back element and are weatherably encapsulated in an encapsulation volume by means of the front element, the back element and the encapsulation material enclosing the solar cells, and
cell connectors which are disposed and designed in such a way that the solar cells are electrically interconnected,
wherein
a metallization of the solar cells and/or the cell connectors are uniformly or largely provided with a protective layer.

2. The solar module as claimed in claim 1, wherein the solar cells each comprise a front metallization and/or a back metallization in the form of finger electrodes, wherein the finger electrodes are uniformly or largely provided with the protective layer, whereas the rest of the front of the solar cell is protective layer-free.

3. The solar module as claimed in claim 1, wherein a material of the protective layer is selected from a group consisting of varnish, polyolefin and/or self-assembled monolayer.

4. The solar module as claimed in claim 3, wherein the self-assembled monolayer comprises a long-chain compound having a functional group that is designed to carry out chemisorption on a metal surface.

5. The solar module as claimed in claim 3, wherein the self-assembled monolayer is based on one or more alkylamines, one or more alkanethiols and/or one or more carboxylic acids.

6. The solar module as claimed in claim 3, wherein the varnish is organic.

7. The solar module as claimed in claim 1, wherein the protective layer is metal-free.

8. The solar module as claimed in claim 1, wherein the encapsulation material is EVA (ethylene vinyl acetate).

9. A method for coating a metallization of a solar cell and/or a cell connector intended for electrical interconnection of multiple solar cells in a solar module, including the step of coating the metallization of the solar cell and/or the cell connector with a metal-free protective layer.
